(19) United States
(12) Patent Application Publication
(10) Pub. No.: US 2026/0364734 A1
(43) Pub. Date: Nov. 19, 2026

(54) POLISHING CONTROL SYSTEM AND FINAL POLISHING EQUIPMENT COMPRISING SAME

(71) Applicant: SK SILTRON CO., LTD., Gumi-si Geongsangbuk-do (KR)

(72) Inventor: Seungwon LEE, Gumi-si (KR)

(21) Appl. No.: 19/154,425

(22) PCT Filed: Jun. 8, 2023
(86) PCT No.: PCT/KR2023/007862

§ 371 Date: Aug. 7, 2025

(30) Foreign Application Priority Data
Feb. 9, 2023 (KR) 10-2023-0017234

(51) Int. Cl. B24B 37/005

(52) U.S. Cl. CPC B24B 37/005

(57) ABSTRACT

The present invention relates to a polishing control system, which can actively control a change in ESFQD (Edge Site flatness Front reference least sQuare Deviation) by means of lifetime elapsing of a polishing pad, and, more specifically, to a polishing control system comprising: a plurality of slurry storage units in which a plurality of slurry solutions with different composition ratios of an alkali solution are stored by composition ratio of the alkali solution; a memory unit in which first data about a wafer edge portion polishing amount according to the lifetime elapsing of the polishing pad and second data regarding wafer edge portion polishing amounts according to the composition ratios of the alkali solution included in the slurry solutions stored in the slurry storage units are stored; and a slurry supply unit for supplying, on the basis of the first data and the second data stored in the memory unit, the slurry solutions stored in the slurry storage units to a polishing table of final polishing equipment.

### CROSS-REFERENCE TO RELATED PATENT APPLICATIONS

This application is a U.S. National Stage Application under 35 U.S.C. § 371 of PCT Application No. PCT/KR2023/007862, filed Jun. 8, 2023, which claims priority to Korean Patent Application No. 10-2023-0017234, filed Feb. 9, 2023, whose entire disclosures are hereby incorporated by reference.

### TECHNICAL FIELD

The present disclosure relates to a polishing control system, and more particularly, to a polishing control system configured to actively control a variation in ESFQD (Edge Site flatness Front reference least sQuare Deviation) over the lifetime of a polishing pad.

### BACKGROUND ART

FIG. 1A is a diagram showing a variation in the quality of “Delta ESFQD” over the lifetime of a pad, and FIG. 1B is a diagram showing a variation in the thickness of a polishing pad over the lifetime of the pad.

In general, as the pad lifetime of a polishing pad progresses, the thickness of the polishing pad decreases. However, the head down position of a polishing head remains constant at all times.

Accordingly, compared to polishing with the polishing pad in a relatively thick state, when polishing is performed with the polishing pad in a relatively thin state, the negative Delta ESFQD value increases due to exposure of the edge region of the wafer being polished, resulting in deterioration in ESFQD.

In this case, Delta ESFQD is a value obtained by subtracting the ESFQD before polishing from the ESFQD after single-sided polishing of the wafer. A larger negative (−) value indicates greater edge roll-off.

### DISCLOSURE

### Technical Problem

An aspect of the present disclosure is to provide a polishing control system configured to actively control ESFQD) over the lifetime of a polishing pad by supplying slurry solutions having different concentrations of an alkaline solution.

The aspects to be accomplished by the present disclosure are not limited to the above-mentioned aspects, and other aspects not mentioned herein will be clearly understood by those skilled in the art from the following description.

### Technical Solution

A polishing control system of the present disclosure for accomplishing the above aspects is applicable to final polishing equipment, and includes a plurality of slurry storage units configured to respectively store a plurality of slurry solutions having different concentrations of an alkaline solution according to the concentrations of the alkaline solution, a memory configured to store first data on an amount of polishing at an edge region of a wafer over a lifetime of a polishing pad and second data on an amount of polishing at the edge region of the wafer depending on the concentrations of the alkaline solution contained in the slurry solutions stored in the slurry storage units, and a slurry supply unit configured to supply the slurry solutions stored in the slurry storage units to a polishing table of the final polishing equipment based on the first data and the second data stored in the memory.

In addition, the slurry solutions may include silica, ammonium hydroxide, water, and a polymer.

In addition, the edge region may be divided into sections in units of length in the diameter direction of the wafer.

In addition, the second data may further include data on an amount of polishing at the edge region of the wafer based on at least one of thickness information of a guide ring relative to a thickness of the wafer, thickness information of a nonwoven fabric, thickness information of a nap layer, polishing pressure information, or polishing time information.

The polishing table may include first to third polishing tables, the slurry storage units may include first to third slurry storage units configured to store first to third samples of slurry having different compositions, and each of the first to third samples may include silica (SiO₂), ammonium hydroxide (NH₄OH), water (H₂O), and a water-soluble polymer. The first to third samples may have the same weight percentages of silica and water-soluble polymer and different weight percentages of ammonium hydroxide and water.

Among the first to third samples, the third sample may have the highest weight percentage of ammonium hydroxide, and the first sample may have the highest weight percentage of water.

In terms of Delta ESFQD after polishing the edge region of the wafer using the first to third samples, the first sample may have a negative value, and the second and third samples may have positive values, with the third sample having the highest value. The Delta ESFQD may be a value obtained by subtracting ESFQD before polishing from the ESFQD after single-sided polishing of the wafer.

When single-sided polishing is performed on the edge using the first to third samples of slurry, the first sample may exhibit the greatest edge roll-off.

A wafer having Delta ESFQD of 0 may be obtained by polishing the wafer using the first sample of slurry for first 50% of a polishing time and the third sample of slurry for remaining 50% of the polishing time.

A wafer having Delta ESFQD of 5 may be obtained by polishing the wafer using the first sample of slurry for first 26% of the polishing time and the third sample of slurry for remaining 74% of the polishing time.

A wafer having Delta ESFQD of −5 may be obtained by polishing the wafer using the first sample of slurry for first 70% of the polishing time and the third sample of slurry for remaining 30% of the polishing time.

In addition, final polishing equipment including the polishing control system described above is provided.

Aspects of the present disclosure are only some of the exemplary embodiments of the present disclosure, and various embodiments in which the technical features of the present disclosure are reflected can be derived and understood by those skilled in the art based on the detailed description of the present disclosure to be described below.

### Advantageous Effects

The polishing control system of the present disclosure described above has the following effects.

First, it may be possible to actively control a variation in ESFQD over the lifetime of a polishing pad, thereby making it possible to provide products that meet customer requirements.

In addition, the ESFQD of a wafer may be controlled by adjusting the concentration of an alkaline solution contained in a slurry solution. Accordingly, when a plurality of slurry solutions having different concentrations of an alkaline solution is used, products having various ESFQDs may be produced using the same polishing equipment.

Furthermore, active control of the ESFQD may be achieved more precisely using data on an amount of polishing at the edge region of the wafer based on at least one of thickness information of a guide ring relative to the thickness of the wafer, thickness information of a nonwoven fabric, thickness information of a nap layer, polishing pressure information, or polishing time information.

The effects achievable through the present disclosure are not limited to the above-mentioned effects, and other effects not mentioned herein will be clearly understood by those skilled in the art from the following description.

### DESCRIPTION OF DRAWINGS

FIGS. 1A and 1B are diagrams showing a variation in the quality of “Delta ESFQD” and a variation in the thickness of a polishing pad over the lifetime of the pad,

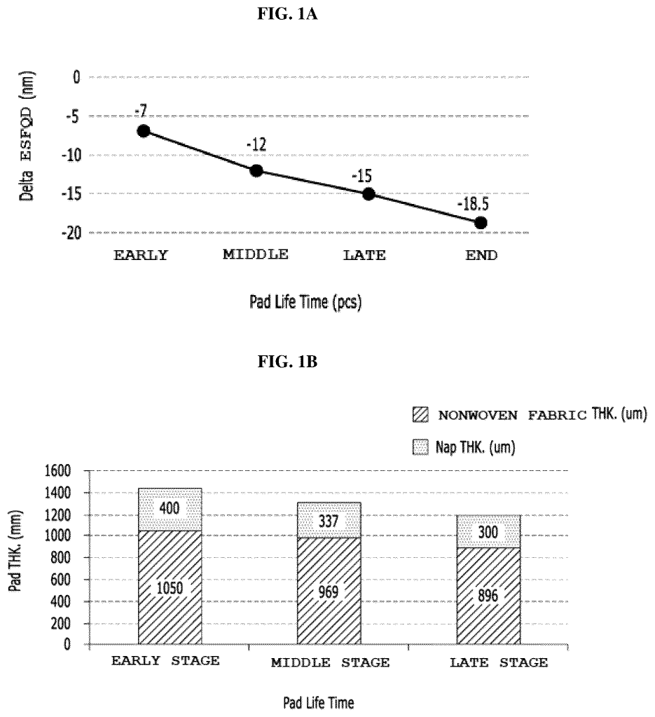

FIG. 2 is a conceptual diagram showing a polishing control system and final polishing equipment including the same according to the present disclosure,

FIGS. 3A and 3B are views conceptually showing a variation in wafer polishing position according to changes in the thickness of the polishing pad, and

FIG. 4 is a diagram showing a polishing profile at an edge region of a wafer, which indicates an edge roll-off control state according to the concentration of an alkaline solution contained in a slurry solution according to the present disclosure.

### BEST MODE

The present disclosure will now be described more fully hereinafter with reference to the accompanying drawings, in which various embodiments are shown.

In the drawings, elements may be exaggerated in size, omitted, or schematically illustrated for clarity and convenience of description. Further, the sizes of elements do not indicate the actual sizes of the elements. Wherever possible, the same reference numerals will be used throughout the drawings to refer to the same parts.

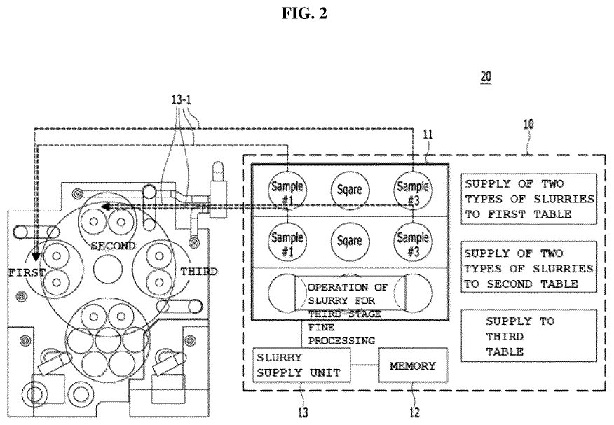

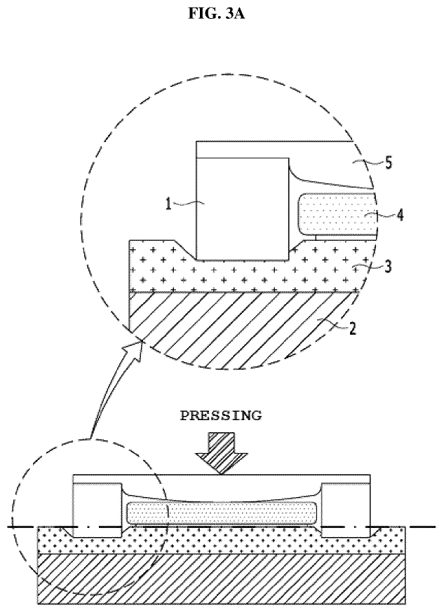

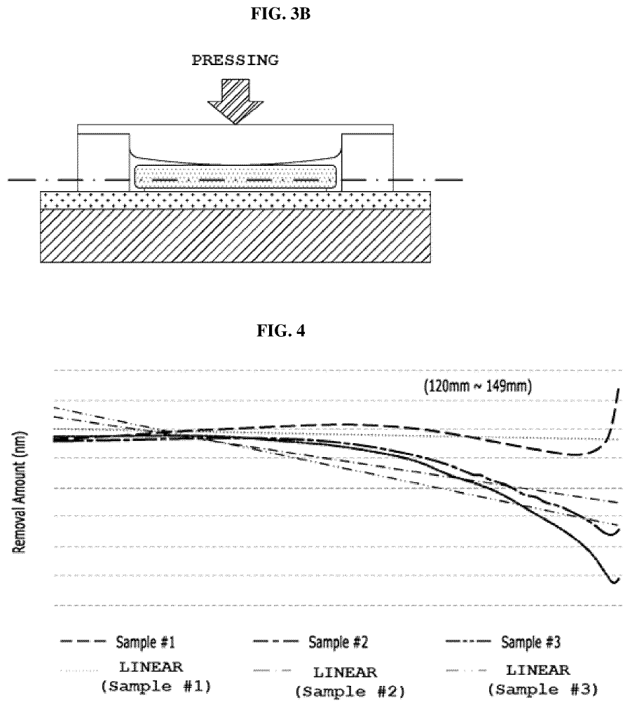

FIG. 2 is a conceptual diagram showing a polishing control system and final polishing equipment including the same according to the present disclosure. FIG. 4 views showing a polishing profile at an edge region of a wafer, which indicates an edge roll-off control state according to the concentration of an alkaline solution contained in a slurry solution according to the present disclosure. FIGS. 3A and 3B are a diagram conceptually showing a variation in wafer polishing position according to changes in the thickness of the polishing pad.

Referring first to FIG. 2, the polishing control system 10 according to the present disclosure is applied to final polishing (FP) equipment 20, and may include a slurry storage unit 11, a memory 12, and a slurry supply unit 13.

A polishing slurry to be supplied during wafer polishing may be stored in the slurry storage unit 11. The slurry storage unit 11 according to the present disclosure may include a plurality of tanks in which a plurality of slurries is stored. A plurality of slurry solutions having different concentrations of an alkaline solution may be stored in the respective slurry tanks.

As one example, the slurry solution may include silica (SiO₂), ammonium hydroxide (NH₄OH), water (H₂O), and a polymer. The weight percentages of silica and polymer may be fixed, and the weight percentages of ammonium hydroxide, which is an alkaline solution, and water may be varied, thereby making it possible to prepare slurry solutions having different alkaline concentrations. The prepared slurry solutions having different alkaline concentrations may be stored in the respective slurry tanks (hereinafter collectively referred to as the “slurry storage unit”).

The reason for configuring the system in this manner is as follows. In single-sided polishing, slurry is supplied from the outer peripheral region of the head, and is delivered toward the inner region of the head (inner region of the wafer) by rotation of the platen. As the alkaline concentration (the amount of ammonium hydroxide) in the slurry increases, the dispersibility between silica and polymer increases, thereby reducing the number of silica-polymer aggregates (coarse particles) and allowing the slurry to effectively penetrate into the central region of the wafer during polishing. Conversely, as the alkaline concentration decreases, the number of coarse particles increases, preventing the slurry from uniformly penetrating into the central region of the wafer and causing the slurry to concentrate on the edge region of the wafer, which in turn increases the polishing rate at the outer peripheral portion of the wafer.

That is, in the case of a high-alkalinity slurry, dispersibility increases, thereby reducing aggregation between polymer and polishing particles in the slurry, which results in decrease in the number of coarse particles. In the case of a low-alkalinity slurry, the opposite effect occurs, leading to increase in the number of coarse particles.

The memory 12 may store first data on an amount of polishing at the edge region of the wafer over the lifetime of the polishing pad and second data on an amount of polishing at the edge region of the wafer depending on the concentration of the alkaline solution contained in the slurry solution stored in the slurry storage unit 11.

The amount of polishing at the edge region of the wafer over the lifetime of the polishing pad, that is, the ESFQD, has been introduced in the Background Art section. The edge polishing flatness achieved by the polishing pad degrades over time. Therefore, the use of the above-described slurry solution with an adjusted alkaline concentration may minimize the degradation in polishing flatness.

The slurry supply unit 13 may be connected to the memory 12 and the slurry storage unit 11 to supply the slurry solution stored in the slurry storage unit 11 to a polishing table of the final polishing equipment 20 based on the first data and the second data. To this end, the slurry supply unit 13 and the memory 12 may be communicatively connected to each other, or the slurry supply unit 13 and the memory 12 may be configured as a single module.

A pipe 13-1 may be mounted between a polishing table (not denoted by a reference numeral) provided on the left side of the final polishing equipment 20 and the slurry storage unit 11. In addition, although not shown, a transfer pump and an on-off valve may be connected to the pipe 13-1. Referring to FIG. 2, the pipe 13-1 may be connected to the slurry storage unit 11 and to a first polishing table and a second polishing table of the final polishing equipment 20. Accordingly, the slurry supply unit 13 may process the first data and the second data received from the memory 12, and may control the transfer pump and the on-off valve to supply the slurry stored in the slurry storage unit 11 to the polishing tables. Further, the slurry supply unit 13 may be configured to control the amount of slurry supplied, a supply time, and a supply amount over time.

Meanwhile, to more precisely control the ESFQD, the second data may further include factors that may affect the ESFQD of the wafer during wafer polishing. The second data may further include data on the polishing amount at the edge region of the wafer based on, for example, at least one of thickness information of a guide ring relative to the thickness of the wafer, thickness information of a nonwoven fabric of the polishing pad, thickness information of a nap layer of the polishing pad, polishing pressure information, or polishing time information.

FIG. 3A conceptually shows a polishing state at an early stage of the lifetime of the polishing pad, and FIG. 3B conceptually shows a polishing state at a late stage of the lifetime of the polishing pad.

As shown, the polishing pad used for final polishing may include an underlying nonwoven fabric layer 2 and an overlying nap layer 3. A wafer 4 may be placed on the nap layer 3, and a guide ring 1 may prevent escape of the wafer 4.

In this case, as the final polishing process progresses, reduction in the thickness of the polishing pad may be identified based on the compression state between the guide ring 1 and the nap layer 3. In detail, at the late stage compared to the early stage, the thickness of the nap layer 3 of the polishing pad decreases, resulting in reduction in contact force between the polishing pad and the head 5. Accordingly, the amount of polishing at the edge region of the wafer 4 may decrease at the late stage compared to the early stage. Therefore, it may be possible to actively control the ESFQD of the wafer 4 by supplying slurries having different alkaline concentrations while adjusting the amount of slurries supplied and the supply time in consideration of the above factors.

Meanwhile, the edge region of the wafer 4 may be divided into sections in units of length in the diameter direction of the wafer. This may follow standard criteria known in this art.

Hereinafter, an embodiment of the present disclosure will be described.

First, the first data may vary depending on the specifications of the final polishing equipment, and thus may be generated based on results obtained by operating respective types of final polishing equipment.

Next, to generate the second data, slurry samples may be prepared by varying the weight percentages of ammonium hydroxide and water as follows.
Sample #1) SiO₂ 9%, NH₄OH 3%, H₂O 87%, Polymer 1%
Sample #2) SiO₂ 9%, NH₄OH 4.5%, H₂O 85.5%, Polymer 1%
Sample #3) SiO₂ 9%, NH₄OH 6%, H₂O 84%, Polymer 1%

The above samples are slurry solutions having a pH of 10.6 using ammonium hydroxide (NH₄OH) as an alkali base, a silica primary size of 35 nm, and a water-soluble polymer with a molecular weight of 1,000,000. These are shown in Table 1 below.

TABLE 1

| Slurry | SiO₂ | NH₄OH | H₂O | Water-Soluble |
|---|---|---|---|---|
| Sample | (wt %) | (wt %) | (wt %) | Polymer (wt %) |
| Sample #1 | 9 | 3.0 | 87.0 | 1 |
| Sample #2 | 9 | 4.5 | 85.5 | 1 |
| Sample #3 | 9 | 6.0 | 84.0 | 1 |

Table 2 below shows the wafer edge roll-off values measured for each alkali concentration.

The polishing profiles at the outer peripheral portion of the wafer by wafer position (mm) in FIG. 4 are results obtained under a pressure of 12 kPa and a polishing time of 150 seconds at the early stage of the lifetime of a suede type polishing pad having a nap hardness of 20 in all of the first, second, and third steps. These results are shown in Table 2 below. Meanwhile, in FIG. 4, the polishing amount (removal amount), which is represented by the vertical axis, can be understood to increase in the upward direction.

TABLE 2

| | Alkali | Delta | Delta | Delta |
|---|---|---|---|---|
| Slurry | Concentration | ESFQD | ZDD148 | ZDD149 |
| Sample | (Relative Ratio %) | (nm) | (nm/mm²) | (nm/mm²) |
| Sample #1 | 100 | −12 | −7.7 | −94.3 |
| Sample #2 | 150 | 4 | 1.0 | −52.2 |
| Sample #3 | 200 | 11 | 4.8 | −44.0 |

Table 2 above shows results obtained at the early stage of the lifetime of the polishing pad. It can be understood that the alkali concentration of Sample #2 is 50% higher than that of Sample #1, and the alkali concentration of Sample #3 is 100% higher than that of Sample #1.

Therefore, when it is desired to obtain “Delta ESFQD=0” in order to maintain the level of “input ESFQD”,
polishing may be performed using Sample #1 for 50% of the total polishing time and Sample #3 for remaining 50% of the total polishing time. When it is desired to obtain “Delta ESFQD=5”, polishing may be performed using Sample #1 for 26% of the total polishing time and Sample #3 for remaining 74% of the total polishing time. When it is desired to obtain “Delta ESFQD=−5”, polishing may be performed using Sample #1 for 70% of the total polishing time and Sample #3 for remaining 30% of the total polishing time. On the other hand, when it is desired to obtain “Delta ESFQD=5” at the end stage of the lifetime of the polishing pad, polishing may be performed using only Sample #3 for a duration 2.1 times longer.

As a result, it can be seen that edge roll-off control may be achieved by adjusting the concentration of alkali (NH₄OH) contained in the slurry.

The polishing control system 10 described above may be applied to and constitute the final polishing equipment 20, as shown in FIG. 2.

That is, the final polishing equipment 20 performs polishing through three polishing tables (first, second, and third steps) in the polishing apparatus. In the third step, which corresponds to the final step of polishing, polishing may be performed using a mild slurry having a low polishing rate, focusing on defect control, and thus may have no influence on flatness. Flatness may be controlled in the first and second polishing tables, in which slurries having a relatively high polishing rate are used.

Accordingly, when it is desired to produce a wafer with a “target ESFQD” in the negative (−) direction at the early stage of the lifetime of the polishing pad,
the polishing recipe may be set such that the usage time of Sample #3 is shorter than that of Sample #1.

In addition, when it is desired to produce a wafer with the “target ESFQD” being “0” or in the positive (+) direction at the late stage of the lifetime of the polishing pad,
the recipe may be set such that the usage time of Sample #3 is longer than that of Sample #1.

In addition, when it is desired to achieve a uniform “Delta ESFQD” value throughout the early, middle, and late stages of the lifetime of the polishing pad,
the “Delta ESFQD” value may be calculated based on the “Delta ESFQD” correlation and the application of Sample #1 and Sample #3 over the lifetime of the polishing pad, and may be controlled in real time based on the calculated value. Accordingly, it may be possible to actively control the “Delta ESFQD” at each stage of the lifetime of the polishing pad.

The features, structures, and effects described in association with the embodiments above are incorporated into at least one embodiment of the present disclosure, but are not limited only to the one embodiment. Furthermore, the features, structures, and effects exemplified in association with respective embodiments can be implemented in other embodiments by combination or modification by those skilled in the art. Therefore, content related to such combinations and modifications should be construed as falling within the scope of the present disclosure.

### INDUSTRIAL APPLICABILITY

The above-described polishing control system and the final polishing equipment including the same may be used to improve the ESFQD of a wafer.

1. A polishing control system applicable to final polishing equipment, the polishing control system comprising:
a plurality of slurry storage units configured to respectively store a plurality of slurry solutions having different concentrations of an alkaline solution according to the concentrations of the alkaline solution;
a memory configured to store first data on an amount of polishing at an edge region of a wafer over a lifetime of a polishing pad and second data on an amount of polishing at the edge region of the wafer depending on the concentrations of the alkaline solution contained in the slurry solutions stored in the slurry storage units; and
a slurry supply unit configured to supply the slurry solutions stored in the slurry storage units to a polishing table of the final polishing equipment based on the first data and the second data stored in the memory.

2. The polishing control system according to claim 1, wherein the slurry solutions comprise silica, ammonium hydroxide, water, and a polymer.

3. The polishing control system according to claim 1, wherein the second data further comprises data on an amount of polishing at the edge region of the wafer based on at least one of thickness information of a guide ring relative to a thickness of the wafer, thickness information of a nonwoven fabric, thickness information of a nap layer, polishing pressure information, or polishing time information.

4. The polishing control system according to claim 1, wherein the polishing table comprises first to third polishing tables, the slurry storage units comprise first to third slurry storage units configured to store first to third samples of slurry having different compositions, and
each of the first to third samples comprises silica (SiO₂), ammonium hydroxide (NH₄OH), water (H₂O), and a water-soluble polymer, the first to third samples having the same weight percentages of silica and water-soluble polymer and different weight percentages of ammonium hydroxide and water.

5. The polishing control system according to claim 4, wherein, among the first to third samples, the third sample has a highest weight percentage of ammonium hydroxide, and the first sample has a highest weight percentage of water.

6. The polishing control system according to claim 5, wherein, in terms of Delta ESFQD after polishing the edge region of the wafer using the first to third samples, the first sample has a negative value, and the second and third samples have positive values, with the third sample having a highest value, the Delta ESFQD being a value obtained by subtracting ESFQD before polishing from the ESFQD after single-sided polishing of the wafer.

7. The polishing control system according to claim 6, wherein, when single-sided polishing is performed on the edge using the first to third samples of slurry, the first sample exhibits greatest edge roll-off.

8. The polishing control system according to claim 6, wherein a wafer having Delta ESFQD of 0 is obtained by polishing the wafer using the first sample of slurry for first 50% of a polishing time and the third sample of slurry for remaining 50% of the polishing time.

9. The polishing control system according to claim 6, wherein a wafer having Delta ESFQD of 5 is obtained by polishing the wafer using the first sample of slurry for first 26% of a polishing time and the third sample of slurry for remaining 74% of the polishing time.

10. The polishing control system according to claim 6, wherein a wafer having Delta ESFQD of −5 is obtained by polishing the wafer using the first sample of slurry for first 70% of a polishing time and the third sample of slurry for remaining 30% of the polishing time.

11. Final polishing equipment, comprising:
a polishing table on which a wafer is disposed;
a polishing pad polishing the wafer; and
a polishing control system supplying a slurry solution having alkaline concentrations adjusted over lifetime of the polishing pad to the polishing table.

12. The final polishing equipment according to claim 11, wherein the polishing control system adjusts the alkaline concentrations according to a target edge sector frontside reference Q deviation (ESFQD) of the wafer.

13. The final polishing equipment according to claim 11, further comprising a pipe disposed between the polishing control system and the polishing table to form a path through which the slurry solution flows.

14. The final polishing equipment according to claim 11, wherein the polishing table comprises first, second, and third polishing tables, and
wherein a polishing rate of the slurry solution supplied to the first and second polishing tables is higher than a polishing rate of the slurry solution supplied to the third polishing table.

15. The final polishing equipment according to claim 11, wherein the polishing pad comprises:
a nonwoven fabric layer;
a nap layer disposed over the nonwoven fabric layer, the wafer being placed on the nap layer; and
a guide ring disposed above the nap layer to prevent escape of the wafer.

16. The final polishing equipment according to claim 15, wherein the polishing control system adjusts the alkaline concentrations in consideration of at least one of thickness information of the guide ring relative to a thickness of the wafer, thickness information of the nonwoven fabric layer, thickness information of the nap layer, polishing pressure information, or polishing time information.

17. The final polishing equipment according to claim 11, wherein the slurry solution includes silica (SiO₂), ammonium hydroxide (NH₄OH), water (H₂O), and a polymer.

18. The final polishing equipment according to claim 17, wherein the polishing control system adjusts the alkaline concentrations by fixing weight percentages of the silica and the polymer and by varying weight percentages of the ammonium hydroxide and the water.

19. The polishing control system according to claim 1, wherein the slurry supply unit and the memory are communicatively connected to each other.

20. The polishing control system according to claim 1, wherein the slurry supply unit and the memory is configured as a single module.
